(19) United States
(12) Patent Application Publication
(10) Pub. No.: US 2025/0065738 A1
(43) Pub. Date: Feb. 27, 2025

(54) BI-DIRECTIONAL LIGHTED CHARGING SYSTEMS AND METHODS

(71) Applicant: Ford Global Technologies, LLC, Dearborn, MI (US)

(72) Inventors: Jacob Michael Haspiel, Ann Arbor, MI (US); Bregt Ectors, Royal Oak, MI (US); Todd Ansbacher, Westland, MI (US)

(73) Assignee: Ford Global Technologies, LLC, Dearborn, MI (US)

(21) Appl. No.: 18/453,930

(22) Filed: Aug. 22, 2023

(51) Int. Cl. B60L 53/18; B60L 53/62; B60L 55/00

(52) U.S. Cl. CPC B60L 53/18; B60L 53/62; B60L 55/00; G07C 5/008

(57) ABSTRACT

A charging system is disclosed. The charging system may include a charging cord body and a light emitting diode (LED) strip. The LED strip may include a plurality of LEDs disposed at a charging cord body exterior surface. The LED strip may be configured to emit light in a plurality of modes. The charging system may further include a processor that may be communicatively coupled to the LED strip. The processor may be configured to obtain charging information associated with at least one of a vehicle and a charging station and select a first mode from the plurality of modes based on the charging information. The processor may activate the LED strip in the first mode. The LED strip visually indicates the charging information associated with at least one of the vehicle and the charging station in the first mode.

### FIELD

The present disclosure relates to a bidirectional lighted charging systems and methods and more particularly to charging systems and methods configured to visually indicate charging information.

### BACKGROUND

Battery electric vehicles (BEVs) and plug-in hybrid electric vehicles are gaining popularity. An Electric Vehicle (EV) operates on electric energy, and a vehicle user charges the vehicle battery using EV chargers.

Sometimes during vehicle charging, charging may be interrupted, and the vehicle may stop receiving charge from a charger or charging station. The user may not be aware of such instances/issues until the user returns to the vehicle or views an application (or “app”) associated with the vehicle on a user device. Thus, the user may not receive any indication associated with the situation from a remote location or if the user does not have access to the user device.

### BRIEF DESCRIPTION OF THE DRAWINGS

The detailed description is set forth with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 depicts an environment in which techniques and structures for providing the systems and methods disclosed herein may be implemented.

FIG. 2 depicts a block diagram of a charging system in accordance with the present disclosure.

FIGS. 3A and 3B depict visual indications associated with charging faults in accordance with the present disclosure.

FIGS. 4A and 4B depict visual indications associated with charging directions in accordance with the present disclosure.

FIGS. 5A and 5B depict visual indications associated with vehicle State of Charge (SoC) levels in accordance with the present disclosure.

FIG. 6 depicts a visual indication associated with vehicle SoC level and charging rate in accordance with the present disclosure.

FIG. 7 depicts a flow diagram of a method for providing visual indication associated with charging information, in accordance with the present disclosure.

### DETAILED DESCRIPTION

### Overview

The present disclosure describes a bidirectional lighted charger system that may be configured to visually indicate charging information to a user. The system may include a charging cord body and a light emitting diode (LED) strip. The charging cord body may be configured to transfer charge/power from a charging station to a vehicle, or from the vehicle to the charging station (or between two vehicles). The LED strip may include a plurality of LEDs that may be disposed on a charging cord body exterior surface. The LED strip may be configured to emit light in a plurality of different modes. The system may further include a charger management unit (“unit”) that may be configured to obtain charging information from at least one of the vehicle and the charging unit. Responsive to obtaining the charging information, the unit may be configured to select a mode from the plurality of modes and may activate the LED strip in the selected mode to visually indicate the charging information to the user.

In some aspects, the charging information may include, but is not limited to, a charging direction (e.g., whether the charge is being transferred from the vehicle to the charging station or from the charging station to the vehicle), a current vehicle State of Charge (SoC) level, a charging speed, charging fault information (e.g., a type of fault if there is a fault in charging the vehicle), a charging rate, and/or the like.

In some aspects, the unit may fetch/obtain a mapping of the plurality of modes with a plurality of light illumination patterns associated with the LEDs included in the LED strip from a memory. Responsive to fetching/obtaining the mapping, the unit may determine a light illumination pattern associated with the selected mode and may activate the LED strip in the selected mode based on the determined light illumination pattern.

In further aspects, the unit may be configured to obtain inputs from an external device and may control LED strip operation based on the obtained inputs. The external device may include, but is not limited to, a proximity sensor, a user device, a third-party device, and/or the like. In some aspects, the unit may obtain user preferences and may control the LED strip operation based on the user preferences.

The present disclosure discloses a system that provides visual indication associated with charging information to a user, which may enable the user to conveniently understand vehicle charging status. For example, the system may provide a visual indication when there may be a fault in charging the vehicle, or may indicate the current SOC level. In addition, the system may illuminate the charging cord, which may enable the user to clearly see/view the charging cord and hence prevent the user from tripping (e.g., during night time).

These and other advantages of the present disclosure are provided in detail herein.

### Illustrative Embodiments

The disclosure will be described more fully hereinafter with reference to the accompanying drawings, in which example embodiments of the disclosure are shown, and not intended to be limiting.

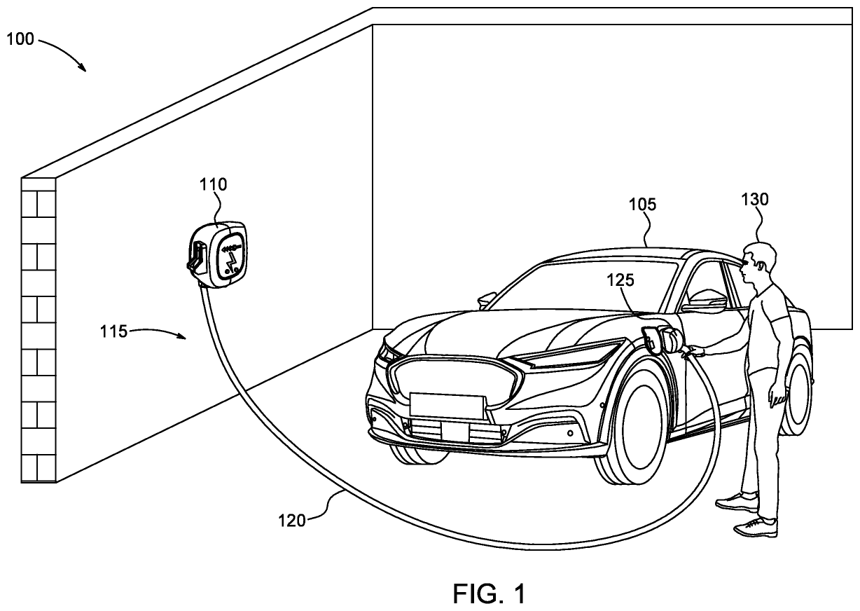

FIG. 1 depicts an example environment 100 in which techniques and structures for providing the systems and methods disclosed herein may be implemented. The environment 100 may include a vehicle 105 that may be a battery electric vehicle (BEV). The vehicle 105 may take the form of any passenger or commercial vehicle such as, for example, an off-road vehicle, a car, a crossover vehicle, a van, a minivan, a bus, a truck, etc. Further, the vehicle 105 may be a manually driven vehicle and/or may be configured to operate in partially or fully autonomous mode. In further aspects, the vehicle 105 may be a plug-in hybrid electric vehicle (PHEV). When the vehicle 105 is PHEV, the vehicle 105 may be equipped with an internal combustion engine that can be employed either alone or in combination with other energy sources to propel the vehicle 105.

The vehicle 105 may include a traction battery or battery pack (not shown) that may provide energy for vehicle propulsion. The battery may be charged by an external power source 110. The external power source 110 may be a charging point/unit (hereinafter referred to as a charging station 110). The charging station 110 may be connected with a connecting device 115 that may connect the charging station 110 and the vehicle 105. The connecting device 115 may include a charging cord 120 that may include a light emitting diode (LED) strip having a plurality of LEDs, which may be configured to emit light in a plurality of modes. The connecting device 115 may further include a charging coupler 125 that may be inserted in the vehicle 105 to enable vehicle charging. In some aspects, power may be transferred from the charging station 110 to the vehicle 105 via the charging cord 120 and the charging coupler 125.

Although FIG. 1 depicts an aspect where the charging coupler 125 is connected/associated with the charging station 110, in some aspects, the charging coupler 125 may be connected/associated with an off-board system (e.g., a grid, a home appliance, another vehicle, and/or the like). If the off-board system is another vehicle, the vehicle 105 may be charged via the charging coupler 125 that enables energy transfer from the other vehicle to the vehicle 105.

When a user 130 desires to charge the vehicle 105, the user 130 may insert the charging coupler 125 into a vehicle connector (not shown) located in the vehicle 105. The vehicle connector may include a plurality of vehicle charger pins that may be configured to receive electric power from the charging coupler 125, thus enabling vehicle charging. In some aspects, the vehicle connector may be a bidirectional connector and may be configured to transmit power from the vehicle 105 to the off-board system. In a similar manner, the charging coupler 125 may be a bidirectional connector that may receive power from the vehicle 105 and may transmit power from the vehicle 105 to the off-board system.

In some aspects, the charging station 110 may be publicly available electrified vehicle charging station that may belong to a third-party. The charging station 110 may be configured to supply alternating current (AC) power or direct current (DC) power to the vehicle 105. The DC power may enable fast charging of vehicle battery. Stated another way, the DC power may provide sufficient charge to the vehicle battery in a relatively short time duration (e.g., 50% in 10-15 minutes). In some aspects, the vehicle 105 may include power converters (not shown) such as AC to DC converter, DC to DC converter, etc. A person ordinarily skilled in the art may appreciate that the AC to DC converter may be used to convert AC power from the charging station 110 to DC power that may be supplied to the vehicle battery. Further, the DC-to-DC converter may be used to convert a first DC voltage to a second DC voltage for different vehicle functions.

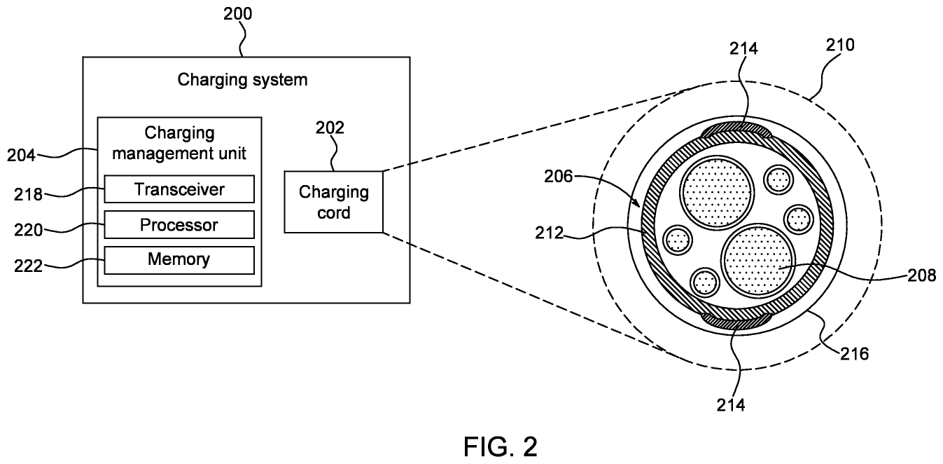

The environment 100 may further include a charging system (shown as charging system 200 in FIG. 2) that may be configured to provide visual indication of charging information. In some aspects, the charging system may be attached to the charging station 110. In further aspects, the charging system may be part of the charging station 110. In additional aspects, a portion of the charging system may be part of the charging station 110. The charging system may be connected to one or more external devices, e.g., a user device (not shown) associated with the user 130, third party devices (e.g., Amazon™ Alexa™), a server, and/or the like, via one or more networks. The server may be associated with a third-party firm or operator that may manage charging station operation.

The network(s) described above illustrates an example communication infrastructure in which the connected devices discussed in various embodiments of this disclosure may communicate. The network(s) may be and/or include the Internet, a private network, public network, or other configuration that operates using any one or more known communication protocols such as, for example, transmission control protocol/Internet protocol (TCP/IP), Bluetooth®, BLE®, Wi-Fi based on the Institute of Electrical and Electronics Engineers (IEEE) standard 802.11, Ultra-Wideband (UWB), and cellular technologies such as Time Division Multiple Access (TDMA), Code Division Multiple Access (CDMA), High-Speed Packet Access (HSPDA), Long-Term Evolution (LTE), Global System for Mobile Communications (GSM), and Fifth Generation (5G), to name a few examples.

The charging system may be configured to obtain charging information associated with at least one of the vehicle 105 and the charging station 110. Responsive to obtaining the charging information, the system may select an operational mode associated with the LED strip (associated with the charging cord 120) and may activate the LED strip in the selected operational mode to provide visual indication associated with the charging information to the user 130. In some aspects, the charging information may include, but is not limited to, a charging direction (e.g., whether the charge is being transferred from the vehicle 105 to the charging station 110 or from the charging station 110 to the vehicle 105), a current vehicle State of Charge (SoC) level, a charging speed, charging fault information (e.g., a type of fault if there is a fault in charging the vehicle 105), a charging rate, and/or the like.

As an example, the charging system may obtain charging fault information (that may be part of the charging information) and may determine a fault type based on the obtained information. Responsive to determining the fault type, the charging system may select a mode associated with the fault type and may illuminate the LED strip based on the fault type. For example, the charging system may illuminate the LED strip in a predefined color (such as red) to visually indicate the fault type to the user 130.

In another example, the charging system may obtain information associated with State of Charge (SoC) level from the vehicle 105 and may illuminate the LED strip such that the LED strip may visually indicate the SoC level. For example, the charging system may illuminate half cord length to indicate 50% SoC level to the user 130. The details of the system are described below in conjunction with subsequent figures.

The vehicle 105, the user 130 and the charging system implement and/or perform operations, as described here in the present disclosure, in accordance with the owner manual and safety guidelines.

FIG. 2 depicts a block diagram of an example charging system 200 in accordance with the present disclosure. The charging system 200 (hereinafter referred as system 200) may include a charging cord 202 and a charging management unit 204 communicatively coupled with the charging cord 202. The charging cord 202 may be same as the charging cord 120 described above in conjunction with FIG. 1. The charging cord 202 may be configured to transfer charge/power from the charging station 110 to the vehicle 105 or from the vehicle 105 to the charging station 110 (or between two vehicles). As described above, the charging cord 202 may include an LED strip (described below) that may operate in a plurality of operational modes (“modes”), and the charging management unit 204 may be configured to select a mode from the plurality of modes and activate the LED strip in the selected mode.

In some aspects, the charging cord 202 may include a charging cord body 206 that may include copper/grounding wires 208 (in addition to insulation), as shown in view 210 of FIG. 2. The copper/grounding wires 208 may be enclosed by a sheath 212 that may be part of the charging cord body 206.

As described above, the charging cord 202 may further include an LED strip 214 that may be disposed at a charging cord body exterior surface. In some aspects, the LED strip 214 may include a plurality of LEDs (e.g., discrete LEDs). In an exemplary aspect, the LED strip 214 may include Red, Green, Blue (RGB) LEDs. The LED strip 214 may be configured to operate or emit light in a plurality of modes. The LED strip 214 may be disposed along an entire charging cord body length and may provide visual indication throughout the charging cord body length. In some aspects, the LED strip 214 may be configured to cover complete charging cord body circumference. In other aspects, the LED strip 214 may be configured to partially cover the charging cord body circumference.

The charging cord 202 may further include a housing 216 that may be configured to enclose the charging cord body 206 and the LED strip 214. The LED strip 214 may be disposed between the charging cord body 206 and the housing 216. In addition, as described above, the LED strip 214 may be disposed along the entire charging cord body length within the housing 216. The housing 216 may be an outer layer that may be made of any material including, but not limited to, silicone, Polyvinyl Chloride (PVC), Vinyl, and/or the like.

As described above, the system 200 may include the charging management unit 204 that may be communicatively coupled with the LED strip 214. In some aspects, the charging management unit 204 may include a transceiver 218, processor 220 and a memory 222, which may be communicatively coupled with each other. The memory 222 may be configured to store a mapping of the plurality of operational modes associated with the LED strip 214 with a plurality of light illumination patterns associated with the plurality of LEDs included in the LED strip 214. The plurality of light illumination patterns comprises at least one of an LED color, an LED brightness or illumination level, an LED pulse pattern, an LED pulse pattern speed, a count of LEDs in the LED strip 214 to be illuminated, and/or the like.

The processor 220 may be disposed in communication with one or more memory devices disposed in communication with the respective computing systems (e.g., the memory 222 and/or one or more external databases not shown in FIG. 2). The processor 220 may utilize the memory 222 to store programs in code and/or to store data for performing aspects in accordance with the disclosure. The memory 222 may be a non-transitory computer-readable storage medium or memory storing a charging management program code. The memory 222 may include any one or a combination of volatile memory elements (e.g., dynamic random-access memory (DRAM), synchronous dynamic random-access memory (SDRAM), etc.) and may include any one or more nonvolatile memory elements (e.g., erasable programmable read-only memory (EPROM), flash memory, electronically erasable programmable read-only memory (EEPROM), programmable read-only memory (PROM), etc.).

The transceiver 218 may be configured to receive information/inputs from one or more devices or systems. For example, the transceiver 218 may be configured to receive charging information from the charging station 110 and/or the vehicle 105 at a predefined frequency. In some aspects, the transceiver 218 may receive the charging information when the charging station 110 may be attached to the vehicle 105 via the charging cord 202. As described above, the charging information may include, but is not limited to, the charging direction (e.g., whether the charge is transferred from the vehicle 105 to the charging station 110 or from the charging station 110 to the vehicle 105), the vehicle SoC level, the charging speed, charging fault information (e.g., a charging fault type), the charging rate, and/or the like. In further aspects, the transceiver 218 may be configured to obtain inputs from user devices and third-party devices (e.g., Amazon™, Alexa™) The inputs may include user instructions/preferences associated with LED strip operation.

In operation, the processor 220 may obtain the charging information from the transceiver 218 when the charging station 110 may be attached to the vehicle 105 via the charging cord 202. Responsive to obtaining the charging information, the processor 220 may select a mode (e.g., a first mode) from the plurality of modes associated with the LED strip 214 based on the obtained charging information, to optimally operate the LED strip 214. The processor 220 may then activate the LED strip 214 in the first mode (or the selected mode). In some aspects, the LED strip 214 may be configured to visually indicate the charging information associated with at least one of the vehicle 105 and the charging station 110 when the LED strip 214 operates in the first mode.

In some aspects, the processor 220 may be further configured to obtain/fetch the mapping of the plurality of modes with the plurality of light illumination patterns from the memory 222. Responsive to obtaining the mapping, the processor 220 may determine a light illumination pattern (from the plurality of illumination patterns) for the plurality of LEDs included in the LED strip 214 associated with the first mode based on the mapping. The processor 220 may then activate the LED strip 214 in the first mode based on the determined light illumination pattern to provide a visual indication associated with the selected/first mode. The details of the visual indication associated with different scenarios/modes are described below in conjunction with subsequent figures.

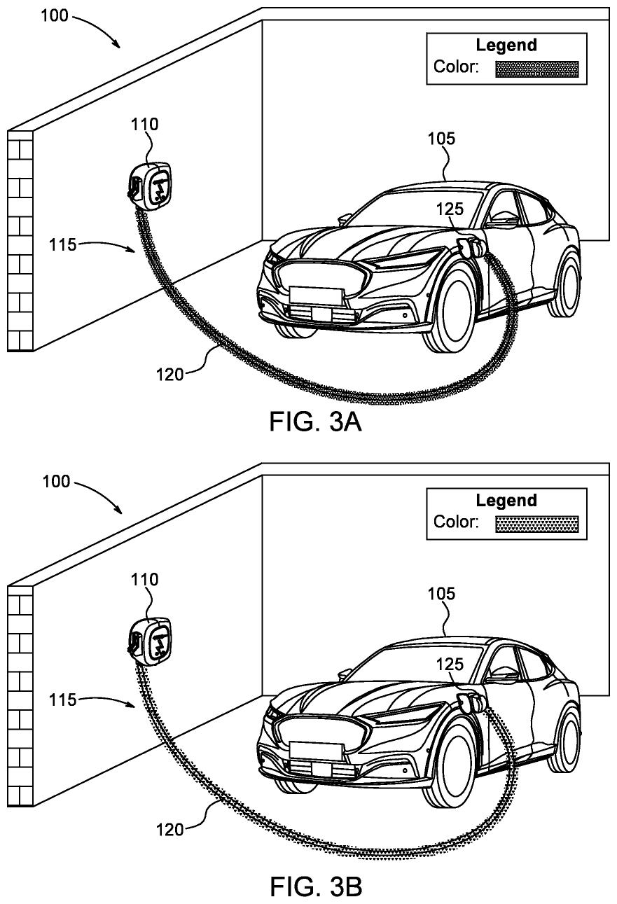

FIGS. 3A and 3B depict example visual indications associated with charging faults in accordance with the present disclosure. As described above, the processor 220 may obtain the charging information (having charging fault information) from the charging station 110 and/or the vehicle 105. Responsive to obtaining the charging information, the processor 220 may determine a fault in charging the vehicle 105 based on the charging information. The processor 220 may then select a mode (e.g., the first mode) from the plurality of modes for the LED strip 214 based on the fault determination.

In additional aspects, responsive to determining that there may be a fault in charging the vehicle 105, the processor 220 may determine a fault type based on the charging information. In some aspects, the processor 220 may select the first mode based on the determined fault type. Responsive to selecting the first mode, the processor 220 may activate the LED strip 214 in the first mode to visually indicate the fault (and the determined fault type).

In some aspects, the processor 220 may determine that the fault in charging may have occurred due to the charging station 110, based on the obtained charging information. Responsive to determining that the fault may have occurred due to the charging station 110, the processor 220 may select a mode (e.g., a second mode) associated with the fault that occurred due to the charging station 110. Responsive to the second mode selection, the processor 220 may identify an LED illumination pattern associated with the second mode (e.g., by using the mapping stored in the memory 222). The processor 220 may then cause the LED strip 214 to illuminate in the second mode such that the LED strip 214 may indicate to the user 130 that there may be a fault in the charging station 110. For example, the processor 220 may cause the LED strip 214 to emit light in a predefined color (and intensity), e.g., red, to visually indicate to the user 130 that the fault may be the charging station 110, as depicted in FIG. 3A. In some aspects, the processor 220 may activate the LEDs throughout the charging cord length to indicate the fault. In further aspects, the processor 220 may cause the LEDs to emit flashing red light to visually indicate the fault in the charging station 110.

In further aspects, the processor 220 may determine that there may be a proximity/pilot fault based on the obtained charging information. In such scenarios, the processor 220 may cause the LED strip 214 to emit light in another color, e.g., orange (as an example), to visually indicate to the user 130 that a proximity/pilot fault may have occurred, as depicted in FIG. 3B. Similar to the aspect described above, in this aspect also, the processor 220 may activate the LEDs throughout the charging cord length to indicate the fault to the user 130. In further aspects, the processor 220 may cause the LEDs to emit flashing orange light to visually indicate the fault.

In additional aspects, the processor 220 may determine that there may be an issue in the connection of the charging coupler 125 and the vehicle connector based on the obtained charging information. In such cases, the processor 220 may illuminate the LED strip 214 in a predefined pattern to visually indicate to the user 130 that the user 130 may not have connected the charging coupler 125 properly.

The LED illumination patterns/colors described above are exemplary in nature and should not be construed as limiting the present disclosure scope. The processor 220 may cause the LED strip 214 to illuminate in any other illumination pattern or color, without departing from the present disclosure scope.

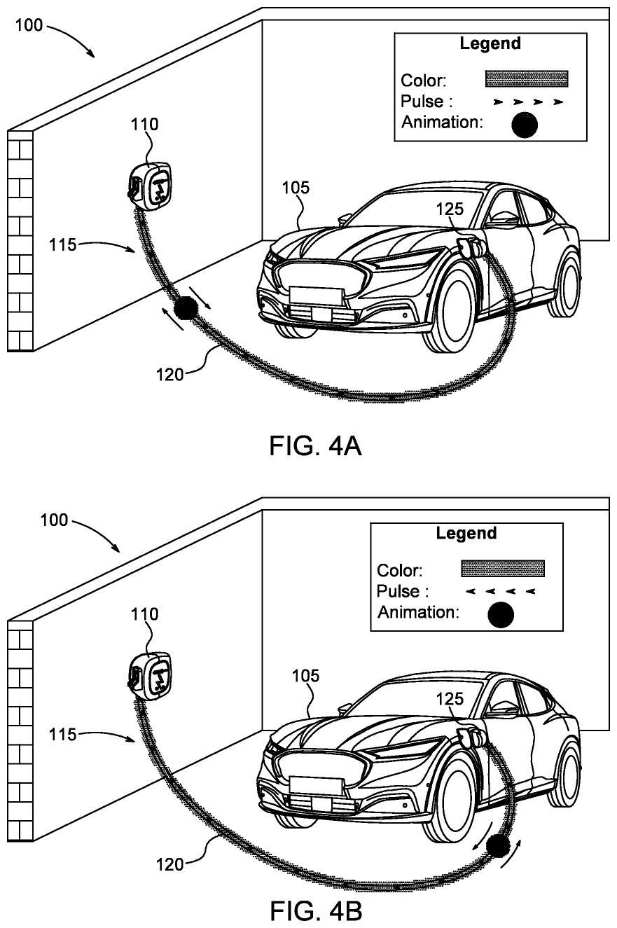

FIGS. 4A and 4B depict example visual indications associated with charging directions in accordance with the present disclosure. As described above in conjunction with FIG. 2, the charging cord 202 (e.g., the charging cord body 206) may be configured to transfer charge from the charging station 110 to the vehicle 105 or from the vehicle 105 to the charging station 110 (or between two vehicles). Also, as described above, the charging information may include the direction of charging.

FIG. 4A depicts a scenario in which the charge may be transferred from the charging station 110 to the vehicle 105, and FIG. 4B depicts a scenario in which the charge may be transferred from the vehicle 105 to the charging station 110. In some aspects, the processor 220 may obtain the information associated with the direction of charging from the charging station 110 and/or the vehicle 105 (e.g., from the charging information). Responsive to obtaining the direction of charging, the processor 220 may select a mode (e.g., a third mode) for the LED strip 214 based on the direction of charging and may activate the LED strip 214 in the selected third mode to visually indicate the direction of charging to the user 130.

In some aspects, responsive to the third mode selection, the processor 220 may identify an illumination pattern associated with the third mode by using the mapping stored in the memory 222. The processor 220 may then cause the LED strip 214 to illuminate in the determined illumination pattern such that the LED strip 214 may indicate the direction of charging. In some aspects, the LED strip 214 may emit a predefined color (in a predefined intensity) to indicate that there is transfer of charge via the charging cord 202 and may generate pulsing pattern using the plurality of LEDs included in the LED strip 214 to indicate the direction of charging. For example, the LED strip 214 may indicate a flow of light pulses from the charging station 110 towards the vehicle 105 when the charge may be getting transferred from the charging station 110 to the vehicle 105 (as shown in FIG. 4A). Similarly, the LED strip 214 may indicate a flow of light pulses from the vehicle 105 towards the charging station 110 when the charge may be getting transferred from the vehicle 105 to the charging station 110 (as shown in FIG. 4B). In further aspects, the processor 220 may obtain information associated with charging rate (e.g., amount of charge added per unit time) from the charging information and may cause an animation via the plurality of LEDs to visually indicate the charging rate to the user 130. The animation may move at a first speed when the charging rate may be low and may move at a second speed when the charging rate may be high.

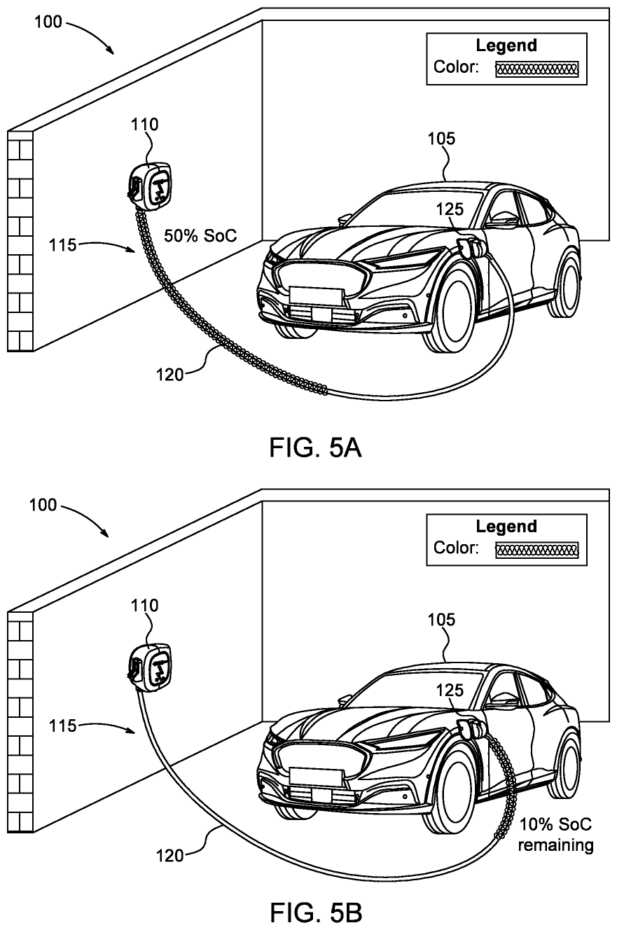

FIGS. 5A and 5B depict example visual indications associated with vehicle State of Charge (SoC) levels in accordance with the present disclosure. In some aspects, FIG. 5A depicts a scenario in which the charge may be getting transferred from the charging station 110 to the vehicle 105, and FIG. 5B depicts a scenario in which the charge may be getting transferred from the vehicle 105 to the charging station 110.

The processor 220 may obtain the information associated with a current SoC level of vehicle battery (e.g., from the charging information that the processor 220 may obtain from the vehicle 105). Responsive to obtaining the current SoC level, the processor 220 may select a mode (e.g., a fourth mode) based on the determined current SoC level and may activate the LED strip 214 in the selected mode to visually indicate the current SoC level.

In some aspects, responsive to the fourth mode selection, the processor 220 may identify an illumination pattern associated with the fourth mode by using the mapping stored in the memory 222. The processor 220 may then cause the LED strip 214 to illuminate in the determined illumination pattern such that the LED strip 214 may indicate the current SoC level to the user 130.

For example, the processor 220 may cause the LED strip 214 to activate a set or predetermined count of LEDs to indicate the current SoC level. The count of LEDs may correspond to the current SoC level. For example, when the current SoC level may be 50%, the LED strip 214 may illuminate LEDs located in half of the charging cord length. In further aspects, the processor 220 may cause the LED strip 214 to emit lights in different colors based on the current SoC level. For example, the LED strip 214 may emit blue light in half charging cord length when the SoC level may be 50% and may emit green light in whole charging cord length when the SoC level may be 100%.

In some aspects, the processor 220 may further obtain the direction of charging and may combine visual indications associated with the current SoC level with the visual indications associated with the direction of charging to illuminate the LED strip 214. The processor 220 may illuminate (or cause to illuminate) a first set/count of LEDs in a predetermined illumination pattern in proximity to the charging station 110 when the charge may be getting transferred from the charging station 110 to the vehicle 105, as shown in FIG. 5A. The first count of LEDs may correspond to the current SoC level. In this manner, the user 130 may get visual indications illustrating that the charge may be getting transferred from the charging station 110 to the vehicle 105, and the current SoC level may be 50% (e.g., when half of the charging cord length may be illuminated). In a similar manner, the processor 220 may illuminate (or cause to illuminate) a second set/count of LEDs in proximity to the vehicle 105 when the charge may be getting transferred from the vehicle 105 to the charging station 110, as shown in FIG. 5B. The second count of LEDs may correspond to the current SoC level or the SoC level “left” in the vehicle 105.

In some aspects, when the charge may be getting transferred from the charging station 110 to the vehicle 105, the LED strip 214 may indicate a percentage of vehicle charge (e.g., whether the vehicle 105 is 50% charged, 75% charged, etc.) by emitting light of different colors and illuminating specific charging cord length from a first cord side/end. On the other hand, when the charge may be getting transferred from the vehicle 105 to the charging station 110, the LED strip 214 may indicate percentage of charge remaining or left in the vehicle 105 (e.g., remaining vehicle SoC level) by emitting light of different colors and illuminating specific charging cord length from a second cord side/end (that may be opposite to the first cord side/end). In this manner, the charging cord 202 may visually indicate the vehicle charging status in both the scenarios, e.g., when the charge may be getting transferred from the charging station 110 to the vehicle 105, and vice versa.

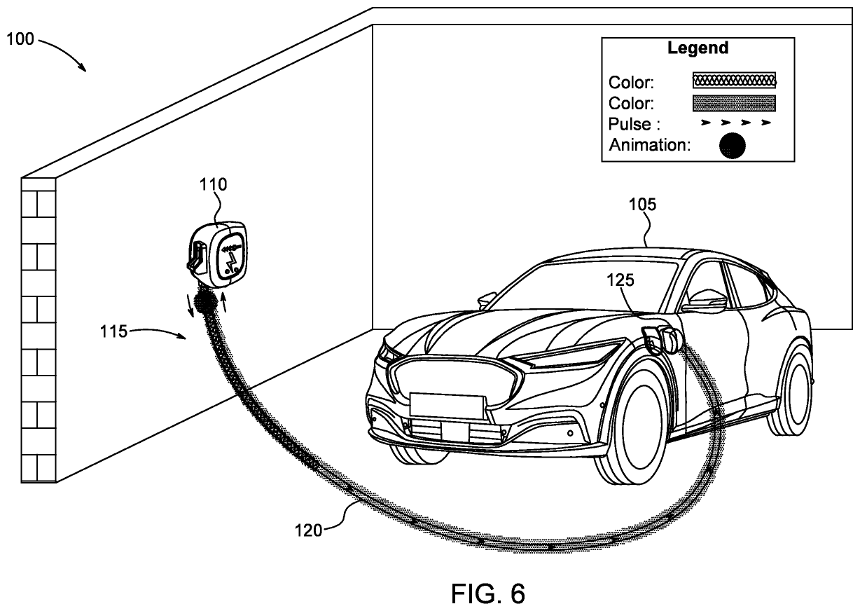

FIG. 6 depicts an example visual indication associated with vehicle SoC level and charging rate in accordance with the present disclosure. As described above, the charging information may include charging rate. The processor 220 may be configured to obtain the charging rate from the charging information and may select/activate a mode for the LED strip 214 to visually indicate the charging rate via the LED strip 214. For example, the processor 220 may control the speed associated with the animation described above to provide a visual indication associated with the charging rate to the user 130.

In some aspects, the processor 220 may obtain the charging information and may cause the LED strip 214 to visually indicate multiple information (e.g., SoC level, charging speed, charging direction, etc.) simultaneously. For example, the processor 220 may cause the LEDs included in the LED strip 214 in the whole charging cord length to illuminate with a first intensity (e.g., a low intensity) to indicate that the vehicle 105 may be charging (or charge is being transferred via the charging cord 202). In addition, the processor 220 may cause the LEDs in half charging cord length to illuminate with a second intensity (e.g., a high intensity) to indicate the current SoC level. Additionally, the processor 220 may cause the LED strip 214 to visually indicate the charging direction, as depicted in FIG. 6. Simultaneous display of different charging information by using the LED strip 214 may help the user 130 to get a holistic view of the charging status.

In further aspects, the processor 220 may be configured to determine information associated with charging speed (e.g., whether the vehicle 105 may be getting charged by using a fast/DC charger) by using the charging information. Responsive to determining the charging speed, the processor 220 may cause the LED strip 214 to visually indicate such charging speed information. For example, the LED strip 214 may emit light in a predetermined color, e.g., purple, when the vehicle 105 may be connected to a DC charger. In a similar manner, the LED strip 214 may visually indicate different information such as information associated with security mode, hands-free charging mode, and/or the like, by illuminating the LED strip 214 in different modes (simultaneously).

In additional aspects, the processor 220 may be configured to obtain inputs/user preferences from external device (e.g., via the transceiver 218). Responsive to obtaining the inputs/user preferences, the processor 220 may operate the LED strip 214 in one or more different operational modes. In an exemplary aspect, the external device may be a user device, a third-party device, a motion sensor, a proximity sensor, and/or the like.

For example, the processor 220 may obtain user preferences associated with LED color to indicate different SoC levels and may illuminate the LEDs included in the LED strip 214 based on user preferred colors. Similarly, the processor 220 may receive user preferences to keep the LEDs off during night time. In addition, the processor 220 may receive one or more LED strip operational instructions from the third-party device and may control the LED strip operation based on the received instructions. For example, the processor 220 may receive the instruction to reduce intensity of the LED strip 214 from the user device/third-party device. Responsive to receiving the instruction, the processor 220 may cause the LED strip 214 to reduce the intensity. In another example, the processor 220 may obtain inputs from the proximity sensor or the motion sensor (e.g., when the user 130 may be in proximity to the charging cord 202) and may illuminate the LED strip 214 in a predefined pattern to enable the user 130 see the charging cord 202 and hence prevent adverse conditions due to tripping, based on the obtained inputs.

In further aspects, the processor 220 may be configured to obtain charging information from a first vehicle (e.g., the vehicle 105) and a second vehicle, when the first vehicle may be connected with the second vehicle for vehicle-to-vehicle charging (and the first vehicle may be connected to the second vehicle via the charging system 200.). Responsive to obtaining the charging information, the processor 220 may be configured select/activate a mode of the LED strip 214 based on the charging information and may visually indicate the charging information. For example, the LED strip 214 may illuminate to show direction of charging, in the manner described above.

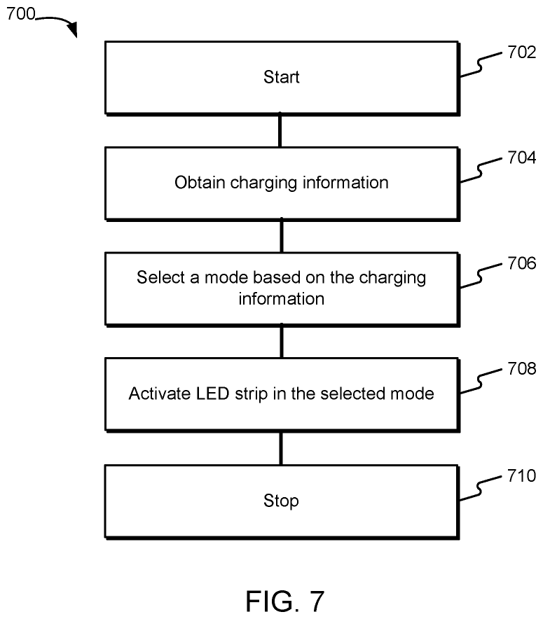

FIG. 7 depicts a flow diagram of an example method 700 for providing visual indication associated with charging information, in accordance with the present disclosure. FIG. 7 may be described with continued reference to prior figures, including FIGS. 1-6. The following process is exemplary and not confined to the steps described hereafter. Moreover, alternative embodiments may include more or less steps than are shown or described herein and may include these steps in a different order than the order described in the following example embodiments.

At step 702, the method 700 may commence. At step 704, the method 700 may include obtaining, by the processor 220, charging information associated with at least one of the charging station 110 and the vehicle 105. Examples of the charging information are described above in conjunction with FIG. 1.

At step 706, the method 700 may include selecting, by the processor 220, a mode from a plurality of modes associated with the LED strip 214 based on the charging information. For example, the processor 220 may select a first mode when there may be a fault in the charging station 110 and may select a second mode when the vehicle 105 may be connected to the DC charger (e.g., for fast charging), and/or the like.

At step 708, the method 700 may include activating, by the processor 220, the LED strip 214 based on the selected mode. In the selected mode, the LED strip 214 may visually indicate the charging information associated with the vehicle 105 and/or the charging station 110 to the user 130.

At step 710, the method 700 may stop.

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a feature, structure, or characteristic is described in connection with an embodiment, one skilled in the art will recognize such feature, structure, or characteristic in connection with other embodiments whether or not explicitly described.

Further, where appropriate, the functions described herein can be performed in one or more of hardware, software, firmware, digital components, or analog components. For example, one or more application specific integrated circuits (ASICs) can be programmed to carry out one or more of the systems and procedures described herein. Certain terms are used throughout the description and claims refer to particular system components. As one skilled in the art will appreciate, components may be referred to by different names. This document does not intend to distinguish between components that differ in name, but not function.

It should also be understood that the word “example” as used herein is intended to be non-exclusionary and non-limiting in nature. More particularly, the word “example” as used herein indicates one among several examples, and it should be understood that no undue emphasis or preference is being directed to the particular example being described.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Computing devices may include computer-executable instructions, where the instructions may be executable by one or more computing devices such as those listed above and stored on a computer-readable medium.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating various embodiments and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

That which is claimed is:

1. A charging system comprising:
a charging cord body;
a light emitting diode (LED) strip comprising a plurality of LEDs disposed about the charging cord body, wherein the LED strip is configured to emit light in a plurality of modes; and
a processor communicatively coupled to the LED strip, wherein the processor is configured to:
obtain charging information associated with at least one of a vehicle and a charging station;
select a first mode from the plurality of modes based on the charging information; and
activate the LED strip in the first mode, wherein the LED strip is configured to visually indicate the charging information associated with at least one of the vehicle and the charging station in the first mode.

2. The charging system of claim 1 further comprising a housing configured to enclose the charging cord body and the LED strip.

3. The charging system of claim 2, wherein the LED strip is disposed along a length of the charging cord body within the housing.

4. The charging system of claim 1, wherein the processor is further configured to:
obtain a mapping of the plurality of modes with a plurality of light illumination patterns, wherein the plurality of light illumination patterns comprises at least one of an LED color, an LED brightness, an LED pulse pattern, an LED pulse pattern speed, and a count of LEDs in the LED strip to be illuminated;
determine a light illumination pattern associated with the first mode based on the mapping; and
activate the LED strip in the first mode based on the light illumination pattern.

5. The charging system of claim 1, wherein the processor is further configured to:
determine a fault in charging the vehicle based on the charging information; and
select the first mode based on a fault determination.

6. The charging system of claim 5, wherein the processor is further configured to determine a charging fault type based on the charging information responsive to determining the fault, and wherein the processor selects the first mode based on the charging fault type.

7. The charging system of claim 1, wherein the charging cord body is configured to transfer charge either from the charging station to the vehicle or from the vehicle to the charging station.

8. The charging system of claim 7, wherein the charging information comprises a direction of charging, and wherein the direction of charging indicates whether the charge is transferred from the charging station to the vehicle or from the vehicle to the charging station.

9. The charging system of claim 8, wherein the charging information comprises a current State of charge (SoC) level of the vehicle.

10. The charging system of claim 9, wherein the processor is configured to:
illuminate a first set of LEDs, from the plurality of LEDs, in the first mode when the charge is transferred from the charging station to the vehicle, wherein illumination of the first set of LEDs is based on the current SoC level; and
illuminate a second set of LEDs, from the plurality of LEDs, in the first mode when the charge is transferred from the vehicle to the charging station, wherein illumination of the second set of LEDs is based on the current SoC level.

11. The charging system of claim 10, wherein the first set of LEDs in proximity to the charging station and the second set of LEDs is in proximity to the vehicle.

12. The charging system of claim 1, wherein the charging information comprises a charging speed.

13. The charging system of claim 1, wherein the charging information comprises a charging rate.

14. The charging system of claim 1, wherein the processor is further configured to:
obtain inputs from an external device; and
control illumination of one or more LEDs from the plurality of LEDs based on the inputs.

15. The charging system of claim 14, wherein the external device comprises a motion sensor.

16. The charging system of claim 14, wherein the external device comprises a user device.

17. A charging system comprising:
a charging cord body;
a light emitting diode (LED) strip comprising a plurality of LEDs disposed about the charging cord body, wherein the LED strip is configured to emit light in a plurality of modes; and
a processor communicatively coupled to the LED strip, wherein the processor is configured to:
obtain charging information associated with at least one of a vehicle and a charging station;
determine a charging fault type associated with a fault in charging the vehicle based on the charging information;
select a first mode from the plurality of modes based on the charging fault type; and
activate the LED strip in the first mode, wherein the LED strip is configured to visually indicate the charging fault type in the first mode.

18. The charging system of claim 17, wherein the processor is further configured to:
obtain a mapping of the plurality of modes with a plurality of light illumination patterns, wherein the plurality of light illumination patterns comprises at least one of an LED color, an LED brightness, an LED pulse pattern, an LED pulse pattern speed, and a count of LEDs in the LED strip to be illuminated;
determine a light illumination pattern associated with the first mode based on the mapping; and
activate the LED strip in the first mode based on the light illumination pattern.

19. The charging system of claim 18 further comprising a housing configured to enclose the charging cord body and the LED strip, wherein the LED strip is disposed along a length of the charging cord body within the housing.

20. A method to indicate charging information, the method comprising:
obtaining, by a processor, charging information associated with at least one of a vehicle and a charging station;
selecting, by the processor, a first mode from a plurality of modes associated with a light emitting diode (LED) strip based on the charging information; and
activating, by the processor, the LED strip in the first mode, wherein the LED strip comprising a plurality of LEDs disposed at an exterior surface of a charging cord body of a charging system, wherein the LED strip is configured to emit light in the plurality of modes, and wherein the LED strip is configured to visually indicate the charging information associated with at least one of the vehicle and the charging station in the first mode.
